(19) United States
(12) Patent Application Publication
(10) Pub. No.: US 2020/0105569 A1
(43) Pub. Date: Apr. 2, 2020

(54) METHODS FOR PROCESSING A SUBSTRATE

(71) Applicant: CORNING INCORPORATED, CORNING, NY (US)

(72) Inventors: Dongyoung Cho, Cheongju-si (KR); Byungchul Kim, Asan City (KR); Ki Nam Kim, Cheonan City (KR); Heechul Kwon, Asan-si (KR)

(21) Appl. No.: 16/611,730

(22) PCT Filed: May 10, 2018
(86) PCT No.: PCT/US18/32058

§ 371 Date: Nov. 7, 2019

(30) Foreign Application Priority Data
May 10, 2017 (KR) 10-2017-0058143

(51) Int. Cl. H01L 21/683; H01L 21/18; H01L 21/67

(52) U.S. Cl. CPC H01L 21/6835; H01L 21/185; H01L 2221/6834; H01L 2221/68345; H01L 21/67288

(57) ABSTRACT

A method of processing a substrate includes bonding a first major surface of the substrate to a major surface of a first carrier, positioning a second carrier with a first major surface of the second carrier facing a second major surface of the substrate, and then applying a force to a location of a second major surface of the second carrier thereby deforming a portion of the second carrier toward the substrate. The deformed portion of the second carrier contacts the second major surface of the substrate thereby deforming a portion of the first major surface and a portion of the second major surface of the substrate toward the first carrier, and the deformed portion of the first major surface of the substrate deforms a portion of the major surface of the first carrier toward an opposing major surface of the first carrier.

### CROSS-REFERENCE TO RELATED APPLICATIONS

This application claims the benefit of priority under 35 U.S.C. § 119 of Korean Patent Application Serial No. 10-2017-0058143 filed on May 10, 2017, the content of which is relied upon and incorporated herein by reference in its entirety.

### FIELD

The present disclosure relates generally to methods and apparatus for processing a substrate and, more particularly, to methods and apparatus for bonding a substrate to a carrier.

### BACKGROUND

Glass sheets are commonly employed in display applications, for example, liquid crystal displays (LCDs), electrophoretic displays (EPD), organic light emitting diode displays (OLEDs), plasma display panels (PDPs), touch sensors, photovoltaics, or the like. Glass sheets are commonly fabricated by flowing molten glass to a forming body whereby a glass ribbon may be formed by a variety of ribbon forming processes, for example, slot draw, float, down-draw, fusion down-draw, rolling, or up-draw. The glass ribbon may then be subsequently divided to provide thin, flexible sheets of glass suitable for further processing into a desired display application including, but not limited to, a substrate for mobile devices, wearables (e.g., watches), televisions, computers, tablets, and other display monitors. There is interest in providing and processing thin, flexible glass sheets in the fabrication of substrates including flexible electronics or other electronic devices. The fabrication of the substrates may include transport and handling of the thin, flexible glass sheets. Thus, there is a demand for apparatus including a substrate and methods for processing the substrate.

In one manner of handling the thin, flexible glass during processing of the substrate, the flexible glass sheet is bonded to a carrier. Once bonded to the carrier, the characteristics and size of the carrier allow the bonded structure to be handled and transported in production without undesired bending of the glass sheet and without causing damage to the glass sheet. For example, a thin, flexible glass sheet may be bonded to a relatively rigid carrier, and then functional components (e.g., a color filter, touch sensor, or thin-film transistor (TFT) components) may be attached to the thin, flexible glass sheet to produce a glass substrate that may be employed in the production of electronic devices for display applications. Additionally, by bonding the glass sheet to the carrier, the characteristics and size of the carrier allow the bonded structure to be handled and transported in production equipment without significant modification to existing production equipment, thus reducing costs and increasing efficiency of the processing techniques. Once transport, handling and other processing steps are complete, there is a desire to remove the substrate from the carrier so that the substrate may be employed, for example, in electronic devices for display applications.

However, given the delicate nature of the substrate, damage may unfortunately occur to the substrate and/or the carrier when bonding the substrate to the carrier, during processing of the substrate and the carrier, and when debonding the substrate from the carrier. Moreover, based at least in part on local strain differences between the substrate and the carrier, the substrate may warp when bonded to the carrier. Warping of the substrate may introduce problems during processing, for example, when attaching functional components (e.g., a color filter, touch sensor, or thin-film transistor (TFT) components) to the substrate. Warping of the substrate may also be undesirable when the substrate is employed in the production of electronic devices for display applications.

Practical solutions for bonding the substrate to the carrier and debonding the substrate from the carrier without damaging the carrier and the substrate are therefore desirable. Likewise, practical solutions for bonding the substrate to the carrier and debonding the substrate from the carrier that at least one of reduce and eliminate warp of the substrate are also desirable. Accordingly, there is a demand for specific apparatus of a carrier and a substrate as well as methods of processing the carrier and the substrate that at least one of reduce and eliminate warp of the substrate and permit bonding of the substrate to the carrier and debonding of the substrate from the carrier without damaging the carrier and the substrate.

### SUMMARY

There are set forth exemplary embodiments of a substrate including a first major surface and a second major surface, a first carrier including a major surface bonded to the first major surface of the substrate, and a second carrier including a major surface bonded to the second major surface of the substrate. Methods of processing the substrate, including bonding the substrate to the first carrier and the second carrier, are also provided.

A substrate, as described throughout the disclosure, includes a wide range of substrates including a single glass substrate (e.g., a single flexible glass substrate, or single rigid glass substrate), a single glass-ceramic substrate, a single ceramic substrate, or a single silicon substrate. As used herein the term “glass” is meant to include any material made at least partially of glass, including glass and glass-ceramics. “Glass-ceramics” include materials produced through controlled crystallization of glass. In embodiments, glass-ceramics have about 30% to about 90% crystallinity. Non-limiting examples of glass ceramic systems that may be employed include Li2O×Al2O3× nSiO2 (i.e. LAS system), MgO×Al2O3×nSiO2 (i.e. MAS system), and ZnO×Al2O3×nSiO2 (i.e. ZAS system). In some embodiments, the substrate includes a single blank substrate of material, for example a single blank glass substrate (e.g., a glass sheet including pristine surfaces separated from a glass ribbon produced by a down-draw fusion process or other technique), a single blank glass-ceramic substrate, a single blank silicon substrate (e.g., a single blank silicon wafer). If provided as a single blank glass substrate, the single blank glass substrate may be transparent, translucent, or opaque and may optionally include the same glass composition throughout the entire thickness of the single blank glass substrate from a first major surface to a second major surface of the single blank glass substrate. In some embodiments, the single blank glass substrate may include a single blank glass substrate that has been chemically strengthened.

Any of the single substrates of the disclosure may optionally include a wide range of functionality. For example, a single glass substrate may include features that allow the substrate to modify light or be incorporated into a display device, touch sensor component, or other device. In some embodiments, the single glass substrate may include color filters, polarizers, thin-film transistors (TFT) or other components. In some embodiments, if the substrate is provided as a single silicon substrate, the silicon substrate may include features that allow the silicon substrate to be incorporated into an integrated circuit, a photovoltaic device, or other electrical component.

In some embodiments, the substrate may include a stack of single substrates, including, for example, any one or more single substrates. The stack of single substrates may be built by two or more single substrates stacked relative to one another with facing major surfaces of adjacent single substrates being bonded relative to one another. In some embodiments, the stack of single substrates may include a stack of single glass substrates. For example, a first single glass substrate may include a color filter and a second single glass substrate may include one or more thin-film transistors. The first and second single glass substrates may be bonded together as a stack of single substrates that may be formed as a display panel for display applications. Accordingly, substrates of the present disclosure may include any one or more single substrates or stack of single substrates.

Some exemplary embodiments of the disclosure are described below with the understanding that any of the embodiments may be used alone or in combination with one another.

### Embodiment 1

A method of processing a substrate includes bonding a first major surface of the substrate to a first major surface of a first carrier, positioning a second carrier with a first major surface of the second carrier facing a second major surface of the substrate, and then applying a force to a location of a second major surface of the second carrier thereby deforming a portion of the first major surface of the second carrier and a portion of the second major surface of the second carrier toward the substrate. The deformed portion of the first major surface of the second carrier contacts the second major surface of the substrate thereby deforming a portion of the first major surface of the substrate and a portion of the second major surface of the substrate toward the first carrier, and the deformed portion of the first major surface of the substrate deforms a portion of the first major surface of the first carrier toward a second major surface of the first carrier.

### Embodiment 2

The method of embodiment 1 further includes ceasing to apply the force to allow a bond front to propagate away from the location, thereby bonding the first major surface of the second carrier to the second major surface of the substrate.

### Embodiment 3

The method of embodiment 1 or embodiment 2, the location defines a point on the second major surface of the second carrier.

### Embodiment 4

The method embodiment 1 or embodiment 2, the location defines an axis extending across the second major surface of the second carrier.

### Embodiment 5

The method of any one of embodiments 1-4, a thickness of the substrate defined between the first major surface of the substrate and the second major surface of the substrate is from about 50 microns to about 300 microns.

### Embodiment 6

The method of any one of embodiments 1-5, material of the substrate is selected from the group consisting of glass, glass-ceramic, ceramic, and silicon.

### Embodiment 7

The method of any one of embodiments 1-6, the first carrier includes polyurethane.

### Embodiment 8

The method of any one of embodiments 1-7, the first carrier includes a first layer including a first material and a second layer including a second material. The first material defines the first major surface of the first carrier, and a stiffness of the second material is greater than a stiffness of the first material.

### Embodiment 9

The method of embodiment 8, the first material is polyurethane.

### Embodiment 10

The method of embodiment 8 or embodiment 9, the second material is selected from the group consisting of glass, glass-ceramic, ceramic, silicon, plastic, and metal.

### Embodiment 11

A method of processing a substrate includes bonding a first major surface of the substrate to a major surface of a first carrier. The first carrier includes a first layer including a first material and a second layer including a second material. The first material defines the major surface of the first carrier, and a stiffness of the second material is greater than a stiffness of the first material. The method then includes bonding a second major surface of the substrate to a major surface of a second carrier, and then debonding the major surface of the first carrier from the first major surface of the substrate.

### Embodiment 12

The method of embodiment 11, a thickness of the substrate defined between the first major surface of the substrate and the second major surface of the substrate is from about 50 microns to about 300 microns.

### Embodiment 13

The method of embodiment 11 or embodiment 12, material of the substrate is selected from the group consisting of glass, glass-ceramic, ceramic, and silicon.

### Embodiment 14

The method of any one of embodiments 11-13, the first material is polyurethane.

### Embodiment 15

The method of any one of embodiments 11-14, the second material is selected from the group consisting of glass, glass-ceramic, ceramic, silicon, plastic, and metal.

### Embodiment 16

The method of any one of embodiments 11-15, an outer peripheral edge of the first carrier laterally circumscribes an outer peripheral edge of the substrate.

### Embodiment 17

The method of any one of embodiments 11-16, an outer peripheral edge of the substrate laterally circumscribes an outer peripheral edge of the second carrier.

### Embodiment 18

The method of any one of embodiments 11-17, a first bond force bonding the first major surface of the substrate to the major surface of the first carrier is less than a second bond force bonding the second major surface of the substrate to the major surface of the second carrier.

### Embodiment 19

The method of any one of embodiments 11-18 further includes separating an outer circumferential portion of the substrate from a central portion of the substrate prior to debonding the major surface of the first carrier from the first major surface of the substrate.

### Embodiment 20

The method of any one of embodiments 11-19 further includes processing an exposed area of the second major surface of the substrate after bonding the first major surface of the substrate to the major surface of the first carrier and prior to bonding the second major surface of the substrate to the major surface of the second carrier.

### Embodiment 21

The method of embodiment 20, the processing the exposed area of the second major surface of the substrate includes washing the exposed area of the second major surface of the substrate with a liquid.

### Embodiment 22

The method of any one of embodiments 11-21 further includes processing an exposed area of the first major surface of the substrate after debonding the major surface of the first carrier from the first major surface of the substrate.

### Embodiment 23

The method of embodiment 22, the processing the exposed area of the first major surface of the substrate includes heating the exposed area of the first major surface of the substrate at a temperature greater than or equal to about 300° C.

### Embodiment 24

The method of any one of embodiments 11-23 further includes debonding the major surface of the second carrier from the second major surface of the substrate after debonding the major surface of the first carrier from the first major surface of the substrate.

### Embodiment 25

The method of any one of embodiment 11-24, the bonding the second major surface of the substrate to the major surface of the second carrier includes positioning the second carrier with the major surface of the second carrier facing the second major surface of the substrate. The method then includes applying a force to a location of an opposing major surface of the second carrier thereby deforming a portion of the major surface and a portion of the opposing major surface of the second carrier toward the substrate. The deformed portion of the major surface of the second carrier contacts the second major surface of the substrate thereby deforming a portion of the first major surface and a portion of the second major surface of the substrate toward the first carrier, and the deformed portion of the first major surface of the substrate deforms a portion of the major surface of the first carrier toward an opposing major surface of the first carrier.

### Embodiment 26

The method of embodiment 25 further includes ceasing to apply the force to allow a bond front to propagate away from the location, thereby bonding the major surface of the second carrier to the second major surface of the substrate.

### Embodiment 27

The method of embodiment 25 or embodiment 26, the location defines a point on the opposing major surface of the second carrier.

### Embodiment 28

The method embodiment 25 or embodiment 26, the location defines an axis extending across the opposing major surface of the second carrier.

### BRIEF DESCRIPTION OF THE DRAWINGS

The above and other features and advantages of embodiments of the present disclosure are better understood when the following detailed description is read with reference to the accompanying drawings, in which:

FIG. 1 illustrates a schematic side view of an exemplary substrate and an exemplary first carrier in accordance with embodiments of the disclosure;

FIG. 2 illustrates an exemplary embodiment of FIG. 1 with the substrate bonded to the first carrier in accordance with embodiments of the disclosure;

FIG. 3 shows a top view of the substrate bonded to the first carrier along line 3-3 of FIG. 2 in accordance with embodiments of the disclosure;

FIG. 4 shows a partial cross-sectional view of the substrate bonded to the first carrier along line 4-4 of FIG. 2 in accordance with embodiments of the disclosure;

FIG. 5 illustrates an exemplary embodiment of the substrate bonded to the first carrier of FIG. 2 including a second carrier in accordance with embodiments of the disclosure;

FIG. 6 illustrates an exemplary embodiment of FIG. 5 with the substrate bonded to the first carrier and the second carrier positioned facing the substrate in accordance with embodiments of the disclosure;

FIG. 7 shows a top view of the substrate bonded to the first carrier and the second carrier positioned facing the substrate along line 7-7 of FIG. 6 in accordance with embodiments of the disclosure;

FIG. 8 shows a partial cross-sectional view of the substrate bonded to the first carrier and the second carrier positioned facing the substrate along line 8-8 of FIG. 6 in accordance with embodiments of the disclosure;

FIG. 9 illustrates an exemplary embodiment of FIG. 6 with the substrate bonded to the first carrier, the second carrier positioned facing the substrate, and a force being applied to a major surface of the second carrier in accordance with embodiments of the disclosure;

FIG. 10 shows a top view of the substrate bonded to the first carrier, the second carrier positioned facing the substrate, and a force being applied to a major surface of the second carrier along line 10-10 of FIG. 9 in accordance with embodiments of the disclosure;

FIG. 11. shows a partial cross-sectional view of the substrate bonded to the first carrier, the second carrier positioned facing the substrate, and a force being applied to a major surface of the second carrier along line 11-11 of FIG. 10 in accordance with embodiments of the disclosure;

FIG. 12 illustrates an exemplary embodiment of the partial cross-sectional view of FIG. 11 after ceasing to apply the force to a major surface of the second carrier with the substrate bonded to the first carrier and the second carrier in accordance with embodiments of the disclosure;

FIG. 13 illustrates an exemplary embodiment of FIG. 9 after ceasing to apply the force to a major surface of the second carrier with the substrate bonded to the first carrier and the second carrier in accordance with embodiments of the disclosure;

FIG. 14 shows a top view of the substrate bonded to the first carrier and the second carrier after ceasing to apply the force to a major surface of the second carrier along line 14-14 of FIG. 13 in accordance with embodiments of the disclosure;

FIG. 15 illustrates an exemplary embodiment of the substrate bonded to the second carrier after debonding the first carrier from the substrate in accordance with embodiments of the disclosure;

FIG. 16 illustrates an exemplary embodiment of the substrate of FIG. 15 after debonding the second carrier from the substrate in accordance with embodiments of the disclosure; and

FIG. 17 shows a flow chart of exemplary methods of processing a substrate in accordance with embodiments of the disclosure.

### DETAILED DESCRIPTION

Embodiments will now be described more fully hereinafter with reference to the accompanying drawings in which exemplary embodiments are shown. Whenever possible, the same reference numerals are used throughout the drawings to refer to the same or like parts. However, claims may encompass many different aspects of various embodiments and should not be construed as limited to the embodiments set forth herein.

As briefly indicated above, in various embodiments there are provided methods and apparatus for processing a substrate. To enable the handling and transport of the substrate during processing, the substrate may be bonded to a carrier. Relative to the substrate, characteristics and size of the carrier may allow the bonded substrate to be handled and transported during processing without significant bending of the substrate that may damage the substrate and/or damage components that may be mounted to the substrate. Unless otherwise noted, the substrate of any of the embodiments of the disclosure may include a single substrate or a stack of two or more single substrates. The single substrates may have a thickness of from about 50 microns to about 300 microns although other thicknesses may be provided in some embodiments.

In some embodiments, a single flexible glass substrate or a stack of single flexible glass substrates may be removably bonded to a carrier using a binding agent, for example a polymer binding agent, silicone binding agents, forces naturally generated between one or more abutting surfaces (e.g., roughened abutting surfaces), or other binding agents. In some embodiments, the substrate may be bonded to the carrier without binding agents, and a bond force based on direct contact between the substrate and the carrier may bond the carrier to the substrate. In some embodiments, the substrate may be bonded to a carrier fabricated from glass, resin or other materials capable of withstanding conditions during processing of the substrate. The carrier may therefore optionally introduce a desired level of rigidity by providing a carrier with additional thickness that may combined with (or acts together with) the thickness of the substrate removably bonded to the carrier. In some embodiments, the carrier may include a plate (e.g., rigid plate) with a thickness that may greater than the thickness of the single substrate bonded to the carrier. Furthermore, in some embodiments, the carrier may be selected to include a thickness where the overall thickness of the carrier and the substrate bonded to the carrier may be within a range that may be employed with processing machinery and equipment configured to process relatively thick glass substrates having a thickness within the range of the overall thickness of the carrier and the substrate bonded to the carrier.

After bonding the substrate to the carrier, there may be a desire to subsequently remove the carrier from the substrate without damaging the substrate. For example, prior to processing the substrate (e.g., by adding one or more functional components), there may be a desire to remove the substrate from the carrier. Alternatively, in some embodiments, there may be a desire to remove the single substrate from the carrier after the substrate has been processed into a single substrate with one or more functional components and prior to creating the substrate as a stack of single substrates. Additionally, in some embodiments, there may be a desire to remove the carrier from the substrate including the stack of single substrates.

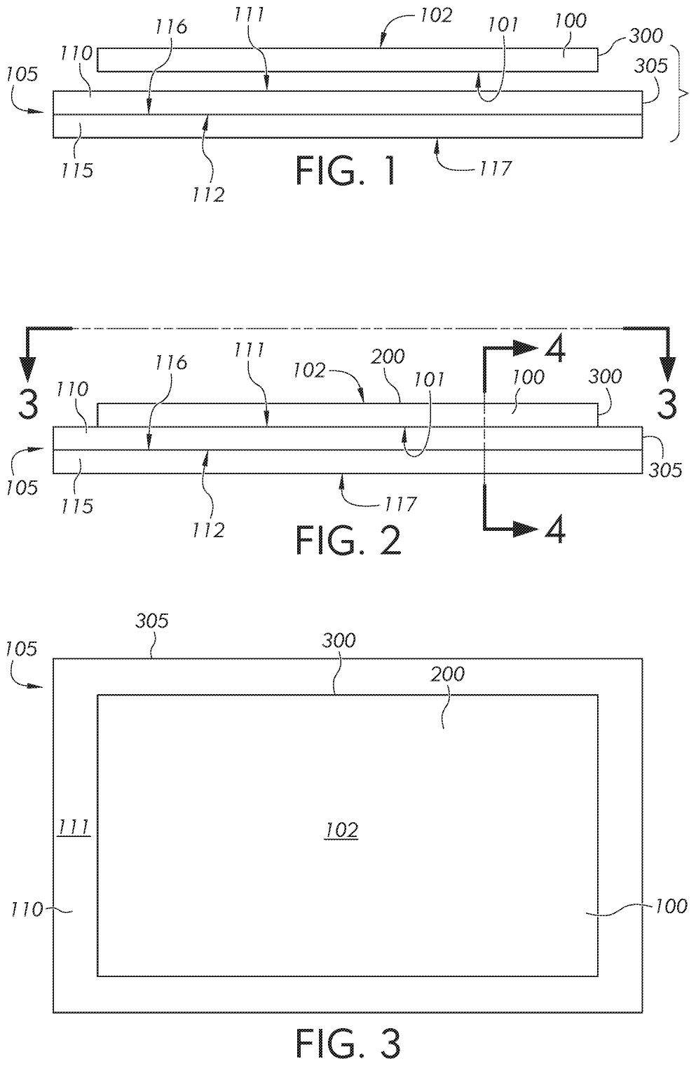

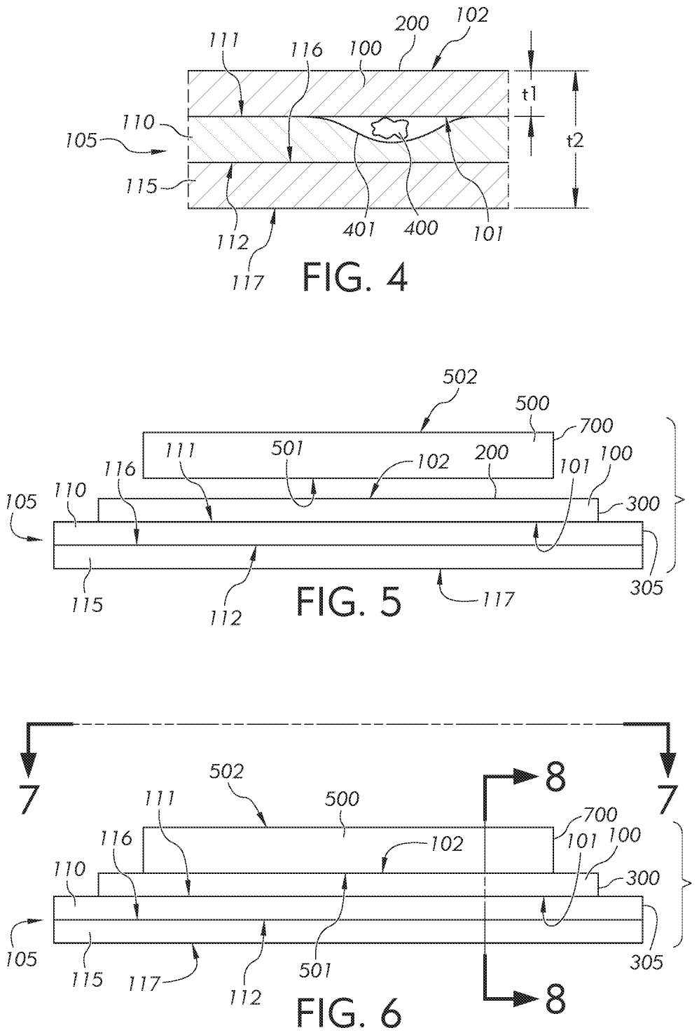

The present disclosure provides methods and apparatus for processing a substrate. For example, FIG. 1 illustrates exemplary features of a substrate 100 including a first major surface 101 and a second major surface 102. In some embodiments, the substrate 100 may include material selected from the group consisting of glass, glass-ceramic, ceramic, and silicon. Additionally, in some embodiments, a thickness “t1” (shown in FIG. 4 and FIG. 12) of the substrate 100 defined between the first major surface 101 of the substrate 100 and the second major surface 102 of the substrate 100 may be from about 50 microns to about 300 microns. In some embodiments, a first carrier 105 may be provided. The first carrier 105 may include a first layer 110 including a first material and a second layer 115 including a second material. In some embodiments, the first layer 110 may include a first major surface 111 and a second major surface 112, and the second layer 115 may include a first major surface 116 and a second major surface 117.

In some embodiments, the second major surface 112 of the first layer 110 of the first carrier 105 may be bonded to the first major surface 116 of the second layer 115 of the first carrier 105. For example, in some embodiments, the second major surface 112 may be in direct contact with the first major surface 116. In some embodiments, based at least on direct contact between the second major surface 112 and the first major surface 116, the second major surface 112 may be directly bonded to the first major surface 116. Alternatively or in addition, in some embodiments, the first carrier 105 may include an adhesive (not shown) positioned between the second major surface 112 and the first major surface 116 to bond the second major surface 112 to the first major surface 116. In some embodiments, the first layer 110 may be bonded to the second layer 115 by lamination, pressing, heating, or other bonding methods to attach the first layer 110 to the second layer 115. In some embodiments, the bond between the second major surface 112 and the first major surface 116 may be considered permanent to the extent that, once bonded, there may be no intention of debonding the second major surface 112 from the first major surface 116.

Moreover, in some embodiments, the first carrier 105 may include only a single layer, or more than two layers, without departing from the scope of the disclosure. For example, in some embodiments, depending on one or more of the mechanical, chemical, and physical properties of the first carrier 105, a single layer, two layers (e.g., first layer 110, second layer 115), or more than two layers may provide characteristics that facilitate bonding between the first carrier 105 and the substrate 100, processing of the first carrier 105 and the substrate 100, and debonding of the substrate 100 from the first carrier 105 in accordance with embodiments of the disclosure. Accordingly, although illustrated in the drawing figures as including the first layer 110 and the second layer 115, it is to be understood that, in some embodiments, the first carrier 105 may include one or more features of the first layer 110 and the second layer 115, either alone or in combination, and may be provided as a single layer or more than two layers, without departing from the scope of the disclosure.

As shown in FIG. 2, in some embodiments, the first material may define the first major surface 111 of the first carrier 105, and a method of processing the substrate 100 may include bonding the first major surface 101 of the substrate 100 to the first major surface 111 of the first carrier 105. In some embodiments, bonding the first major surface 101 of the substrate 100 to the first major surface 111 of the first carrier 105 may include applying pressure to the substrate 100 to bond the substrate 100 to the first carrier 105. The first layer 110 may, therefore, be chosen to provide one or more mechanical, chemical, and physical properties that facilitate bonding between the first major surface 101 of the substrate 100 and the first major surface 111 of the first layer 110 of the first carrier 105. Likewise, the second layer 115 may, therefore, be chosen to provide one or more mechanical, chemical, and physical properties that facilitate processing, handling, and transport of the substrate 100.

For example, in some embodiments, the first material of the first layer 110 may be polyurethane. Additionally, in some embodiments, the second material of the second layer 115 may be selected from the group consisting of glass, glass-ceramic, ceramic, silicon, plastic, and metal. In some embodiments, polyurethane may provide one or more mechanical, chemical, and physical properties that facilitate bonding between the first major surface 101 of the substrate 100 and the first major surface 111 of the first layer 110 of the first carrier 105. Likewise, in some embodiments, glass, glass-ceramic, ceramic, silicon, plastic, and metal may provide one or more mechanical, chemical, and physical properties that facilitate processing, handling, and transport of the substrate 100. For example, in some embodiments, while polyurethane may provide one or more mechanical, chemical, and physical properties that facilitate bonding between the first major surface 101 of the substrate 100 and the first major surface 111 of the first layer 110 of the first carrier 105, polyurethane may provide one or more other mechanical, chemical, and physical properties that are less suitable for processing, handling, and transport of the substrate 100 than, for example, glass, glass-ceramic, ceramic, silicon, plastic, and metal. Alternatively, in some embodiments, while glass, glass-ceramic, ceramic, silicon, plastic, and metal may provide one or more other mechanical, chemical, and physical properties that facilitate processing, handling, and transport of the substrate 100, glass, glass-ceramic, ceramic, silicon, plastic, and metal may provide one or more mechanical, chemical, and physical properties that are less suitable for bonding between the first major surface 101 of the substrate 100 and the first major surface 111 of the first layer 110 of the first carrier 105 than, for example, polyurethane. Thus, in some embodiments, manufacturing the first carrier 105 to include a first layer 110 including a first material and a second layer 115 to include a second material may provide a combination of one or more mechanical, chemical, and physical properties that satisfy specific characteristics that facilitate bonding, processing, handling, and transport of the substrate 100 in accordance with embodiments of the disclosure.

For example, in some embodiments, a stiffness (e.g., elastic modulus) of the second material of the second layer 115 may be greater than a stiffness (e.g., elastic modulus) of the first material of the first layer 110. Thus, in some embodiments, the second layer 115 may provide the first carrier 105 with a layer that may be more rigid than the first layer 110, while the first layer 110 provides the substrate 100 with a layer that may be more flexible than the second layer 115. Accordingly, in some embodiments, an effective stiffness of the first carrier 105 (e.g., a combined stiffness of the stiffness of the first layer 110 and the stiffness of the second layer 115) may be chosen to provide the first carrier 105 with a stiffness (e.g., effective flexibility, effective rigidity) that facilitates bonding, processing, handling, and transport of the substrate 100 in accordance with embodiments of the disclosure.

Providing the second layer 115 of the first carrier 105 with a stiffness greater than the stiffness of the first layer 110 of the first carrier 105 may provide several advantages. For example, during processing, handling, and transport of the substrate 100, it may be desirable to have a rigid structure that at least of one of reduces and eliminates bending of the substrate 100. Additionally, in some embodiments, the substrate 100 may be subjected to contact with objects and external forces during processing, handling, and transport of the substrate 100. Thus, the second layer 115, either alone or in combination with the first layer 110, may provide a stiffness of the first carrier 105 that may be sufficiently rigid to at least one of reduce and eliminate bending of the substrate 100 during processing, handling, and transport of the substrate 100.

Turning to FIG. 3, which illustrates a top view of the substrate 100 bonded to the first carrier 105 along line 3-3 of FIG. 2, in some embodiments, an outer peripheral edge 305 of the first carrier 105 may laterally circumscribe an outer peripheral edge 300 of the substrate 100. Throughout the disclosure, a first edge that “laterally circumscribes” a second edge is intended to mean that, in a top view in a direction perpendicular to one or more of the major surfaces of substrates or carriers in a stack that are exploded and/or bonded to one another, the outer periphery defined by the first edge surrounds the outer periphery defined by the second edge. Thus, for example, as shown in the top view of FIG. 3, the outer periphery defined by the outer peripheral edge 305 of the first carrier 105 surrounds the outer periphery defined by the outer peripheral edge 300 of the substrate 100. Consequently, referring to FIGS. 1 and 2, the outer peripheral edge 305 of the first carrier 105 is shown to laterally circumscribe the outer peripheral edge 300 of the substrate 100.

By laterally circumscribing the outer peripheral edge 300 of the substrate 100, the outer peripheral edge 305 of the first carrier 105 may isolate the outer peripheral edge 300 of the substrate 100 from contact with objects and external forces to which at least one of the substrate 100 and the first carrier 105 may be subjected. For example, during handling, processing, and transport of the substrate 100 bonded to the first carrier 105, at least one of the substrate 100 and the first carrier 105 may be subjected to contact with objects and external forces. In some embodiments, if the substrate 100 was to be directly subjected to contact with objects and external forces, the substrate 100 may become damaged (e.g., cracked, chipped, scratched, etc.) based at least on the contact with the objects and external forces. However, by laterally circumscribing the outer peripheral edge 300 of the substrate 100, the outer peripheral edge 305 of the first carrier 105 may contact the objects and external forces and isolate the outer peripheral edge 300 of the substrate 100 from direct contact with the objects and external forces, thereby at least one of preventing and reducing damage to the substrate 100.

Providing the first layer 110 of the first carrier 105 with a stiffness less than the stiffness of the second layer 115 of the first carrier 105 may provide several advantages. For example, FIG. 4 illustrates a partial cross-sectional view of the substrate 100 bonded to the first carrier 105 along line 4-4 of FIG. 2. As shown, in some embodiments, the first layer 110 may deform to include a pocket 401 in which undesired debris 400 (e.g., dust, dirt, particles, etc.) may be deposited. For example, based at least on the stiffness (e.g., elasticity) of the first layer 110, during bonding, the first layer may deform to include the pocket 401 to accommodate the undesired debris 400 that may be present on at least one of the first major surface 101 of the substrate 100 and the first major surface 111 of the first carrier 105. As the formed pocket 401 contains the debris 400, the substrate 100 may maintain a planar profile (e.g., the first major surface 101 may be planar, the second major surface 102 may be planar, and the first major surface 101 may be parallel to the second major surface 102). That is, if the first material of the first layer 110 was to have a stiffness where the first material did not deform to include the pocket 401, the debris 400 may cause the substrate 100 to warp and have a non-planar profile (e.g., the first major surface 101 may be non-planar, the second major surface 102 may be non-planar, and the first major surface 101 may be non-parallel to the second major surface 102). Warping of the substrate may introduce problems during processing, for example, when attaching functional components (e.g., a color filter, touch sensor, or thin-film transistor (TFT) components) to the substrate 100. Warping of the substrate may also be undesirable when the substrate is employed, for example, in the production of electronic devices for display applications. Accordingly, bonding the substrate 100 to the first carrier 105 in a manner that reduces and/or eliminates warping of the substrate 100 may provide advantages related to processing and utilization of the substrate 100.

Additionally, in some embodiments, polyurethane may provide one or more mechanical, chemical, and physical properties that facilitate bonding between the first major surface 101 of the substrate 100 and the first major surface 111 of the first layer 110 of the first carrier 105. For example, in some embodiments, polyurethane may include self-adhesive properties, where the first major surface 101 of the substrate 100 bonds to the first major surface 111 of the first layer 110 of the first carrier 105 without a bonding agent (e.g., adhesive) and without heating, moistening, or other external influence. Accordingly, polyurethane may provide a surface to which the substrate 100 may be bonded and debonded without leaving residue on the substrate 100. In some embodiments, residue on the substrate 100 may interfere with or degrade optical characteristics of the substrate 100, may desirably be cleaned off of the substrate, and may therefore add to the expense and time of processing the substrate 100. Accordingly, the self-adhesive properties of the polyurethane may, in some embodiments, provide additional advantages relative to bonding the first major surface 101 of the substrate 100 to the first major surface 111 of the first carrier 105 that at least one of reduce and eliminate residue on the substrate 100. Features of the present disclosure may, therefore, improve the quality and efficiency of processing of the substrate 100, thereby reducing costs and providing increased output of substrates for use in a variety of display applications, for example.

As shown in FIGS. 2-4, in some embodiments, after bonding the first major surface 101 of the substrate 100 to the first major surface 111 of the first carrier 105, the substrate 100 may be processed. For example, an exposed area 200 of the second major surface 102 of the substrate 100 may be processed. In some embodiments, processing may be performed by employing existing production equipment in which a bonded structure including the substrate 100 bonded to the first carrier 105 provides, for example, characteristics and size that allow the bonded structure to be handled and transported in the production equipment without significant modification to the production equipment. For example, in some embodiments, existing production equipment may be configured to process a structure having a predetermined thickness. In some embodiments, the thickness “t1” of the substrate 100 in combination with a thickness of the first carrier 105 may be selected to provide a thickness “t2” of the bonded structure, between the second major surface 102 of the substrate 100 and the second major surface 117 of the first carrier 105, equal to the predetermined thickness for which existing production equipment may be configured to process. In some embodiments, the thickness “t2” may be from about 300 microns to about 750 microns, from about 300 microns to about 1 millimeter, from about 1 millimeter to about 2 millimeters; however, in some embodiments, the thickness “t2” of the bonded structure may be greater than or less than the explicit dimensions provided in the disclosure without departing from the scope of the disclosure.

In some embodiments, processing the exposed area 200 of the second major surface 102 of the substrate 100 may include washing the exposed area 200 with a liquid. In some embodiments, washing the exposed area 200 with a liquid may remove debris (e.g., dirt, dust, particles, etc.) that may be deposited on the exposed area 200. Moreover, in some embodiments, processing the substrate 100 may include heating at a temperature greater than about 300 degrees Celsius. For example, in some embodiments, processing the substrate 100 may include attaching functional components (e.g., a color filter, touch sensor, or thin-film transistor (TFT) components) to the substrate 100 during which the substrate 100 may be heated at a temperature greater than about 300 degrees Celsius. However, in embodiments, where the first carrier 105 includes polyurethane material, heating at a temperature greater than about 300 degrees Celsius may degrade the polyurethane. Accordingly, in embodiments where processing includes heating at a temperature greater than about 300 degrees Celsius, it may be desirable to debond the substrate 100 from the first carrier 105 prior to heating at a temperature greater than about 300 degrees Celsius to avoid degradation of the polyurethane material. However, bonding the substrate 100 to a carrier provides a bonded structure with, for example, characteristics and size that allow the bonded structure to be handled and transported in production equipment without significant modification to existing production equipment. Thus, in some embodiments, it may be desirable to bond the substrate 100 to a carrier manufactured from material that may withstand processing, including heating at a temperature greater than about 300 degrees Celsius, without degradation of the material.

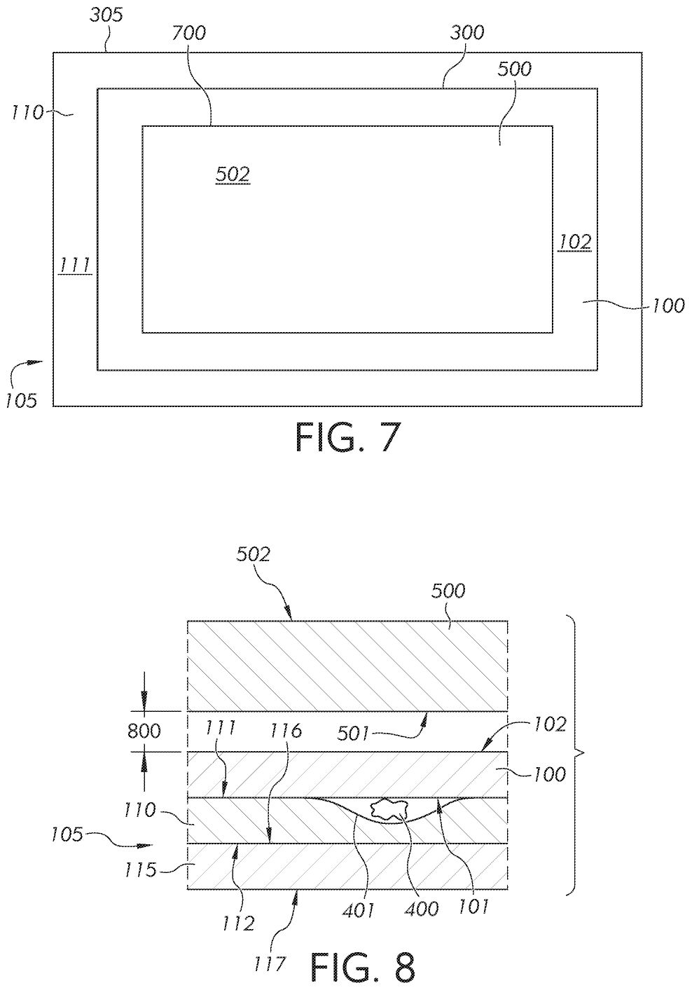

FIGS. 5-12 illustrate exemplary methods of bonding the substrate 100 to a second carrier 500. In some embodiments, the second carrier 500 may be manufactured from material that may withstand processing, including heating at a temperature greater than about 300 degrees Celsius, without degradation of the material. For example, in some embodiments, the second carrier 500 may include a material selected from the group consisting of glass, glass-ceramic, ceramic, silicon, plastic, and metal. As shown in FIG. 5 and FIG. 6, the second carrier 500 may include a first major surface 501 and a second major surface 502. In some embodiments, after bonding the first major surface 101 of the substrate 100 to the first major surface 111 of the first carrier 105, the method may include positioning the second carrier 500 with the first major surface 501 of the second carrier 500 facing the second major surface 102 of the substrate 100. FIG. 7 illustrates a top view of the substrate 100 with the first major surface 501 of the second carrier 500 facing the second major surface 102 of the substrate 100 along line 7-7 of FIG. 6. As shown, in some embodiments, the outer peripheral edge 300 of the substrate 100 may laterally circumscribe an outer peripheral edge 700 of the second carrier 500. By laterally circumscribing the outer peripheral edge 700 of the second carrier 500, the outer peripheral edge 300 of the substrate 100 may be exposed during subsequent handling, processing, and transport of the substrate 100 bonded to the second carrier 500. Additionally, by laterally circumscribing the outer peripheral edge 700 of the second carrier 500, the second carrier 500 may be laterally positioned entirely within the outer peripheral edge 300 of the substrate 100 such that the entire first major surface 501 of the second carrier 500 may be bonded to the second major surface 102 of the substrate 100.

Alternatively, in some embodiments, the outer peripheral edge 700 of the second carrier 500 may laterally circumscribe the outer peripheral edge 300 of the substrate 100. By laterally circumscribing the outer peripheral edge 300 of the substrate 100, the outer peripheral edge 700 of the second carrier 500 may isolate the outer peripheral edge 300 of the substrate 100 from contact with objects and external forces to which at least one of the substrate 100 and the second carrier 500 may be subjected. For example, during handling, processing, and transport of the substrate 100 bonded to the second carrier 500, at least one of the substrate 100 and the second carrier 500 may be subjected to contact with objects and external forces. In some embodiments, if the substrate 100 was to be directly subjected to contact with objects and external forces, the substrate 100 may become damaged (e.g., cracked, chipped, scratched, etc.) based at least on the contact with the objects and external forces. However, by laterally circumscribing the outer peripheral edge 300 of the substrate 100, the outer peripheral edge 700 of the second carrier 500 may contact the objects and external forces and isolate the outer peripheral edge 300 of the substrate 100 from direct contact with the objects and external forces, thereby at least one of preventing and reducing damage to the substrate 100. In some embodiments, the outer peripheral edge 700 of the second carrier 500 and the outer peripheral edge 300 of the substrate 100 may be substantially aligned with one another, i.e., neither the outer peripheral edge 700 laterally circumscribes the outer peripheral edge 300, nor the outer peripheral edge 300 laterally circumscribes the outer peripheral edge 700. The outer peripheral edges 300, 700 may be substantially aligned as when the substrate 100 is trimmed to fit the size of the carrier 500 after having been bonded to the carrier 500.

FIG. 8 illustrates a partial cross-sectional view of the second carrier 500 positioned with the first major surface 501 of the second carrier 500 facing the second major surface 102 of the substrate 100 along line 8-8 of FIG. 6. As shown, in some embodiments, a gap 800 may exist between at least a portion of the first major surface 501 of the second carrier 500 and the second major surface 102 of the substrate 100 when the second carrier 500 is positioned with the first major surface 501 facing the second major surface 102. Without intending to be bound by theory, it is believed that, in some embodiments, when the second carrier 500 is positioned with the first major surface 501 facing the second major surface 102, and no external forces, excluding the force of gravity, act on the substrate 100, the gap 800 may exist between the first major surface 501 of the second carrier 500 and the second major surface 102 of the substrate 100 based at least in part on gas (e.g., air) being trapped between the first major surface 501 and the second major surface 102. Based at least on the presence of the gap 800 between the first major surface 501 and the second major surface 102, the second carrier 500 may be considered to not yet be bonded to the substrate 100.

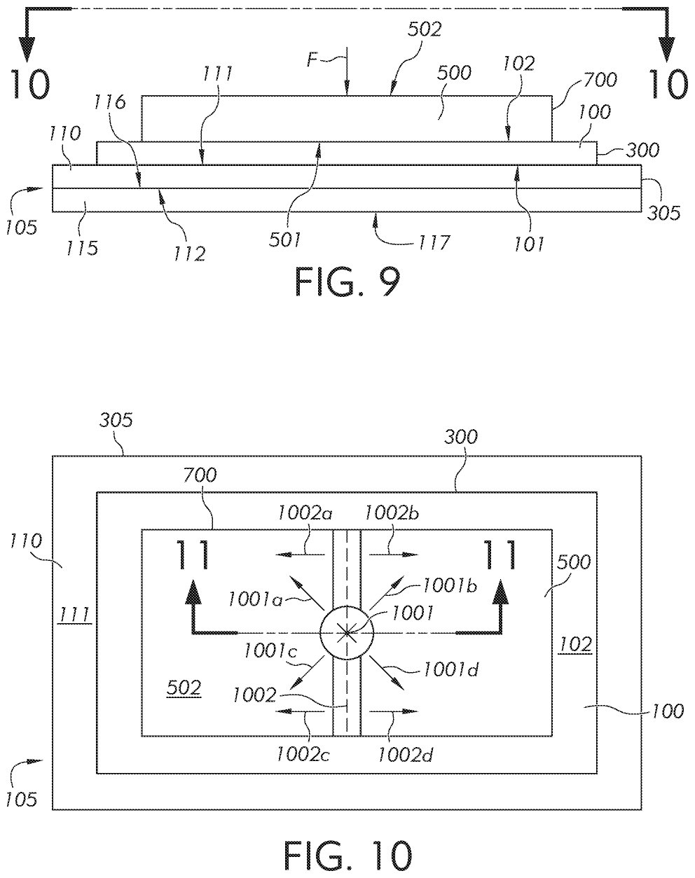

As shown in FIG. 9, in some embodiments, bonding the second carrier 500 to the substrate 100 may include applying a force “F” to a location of the second major surface 502 of the second carrier 500. As shown in FIG. 10, in some embodiments, the location to which the force “F” may be applied may define a point 1001 on the second major surface 502 of the second carrier 500. Additionally, in some embodiments, the location to which the force “F” may be applied may define an axis 1002 extending across the second major surface 502 of the second carrier 500. Although illustrated as being positioned along a geometric centerline of the second major surface 502 of the second carrier 500, it is to be understood that the location to which the force “F” may be applied may be positioned at any location on the second major surface 502 of the second carrier 500 within the outer peripheral edge 700 of the second carrier 500. In some embodiments, the force “F” may be applied perpendicular to the second major surface 502 of the second carrier 500 in a direction toward the substrate 100. In some embodiments, the force “F” may be applied at an angle (e.g. 45 degrees, 60 degrees, 75 degrees, 80 degrees, 85 degrees) relative to the second major surface 502 of the second carrier 500 in a direction toward the substrate 100. Additionally, in some embodiments, the force “F” may be applied to the location of the second major surface 502 of the second carrier 500 with a tool (not shown) that may include one or more of a mechanical structure that contacts the second major surface 502 of the second carrier 500. In some embodiments, the tool may include, for example, a fingertip of a human hand, a robotic device, or any other mechanical structure that contacts the second major surface 502 of the second carrier 500 and applies a force “F” to the location.

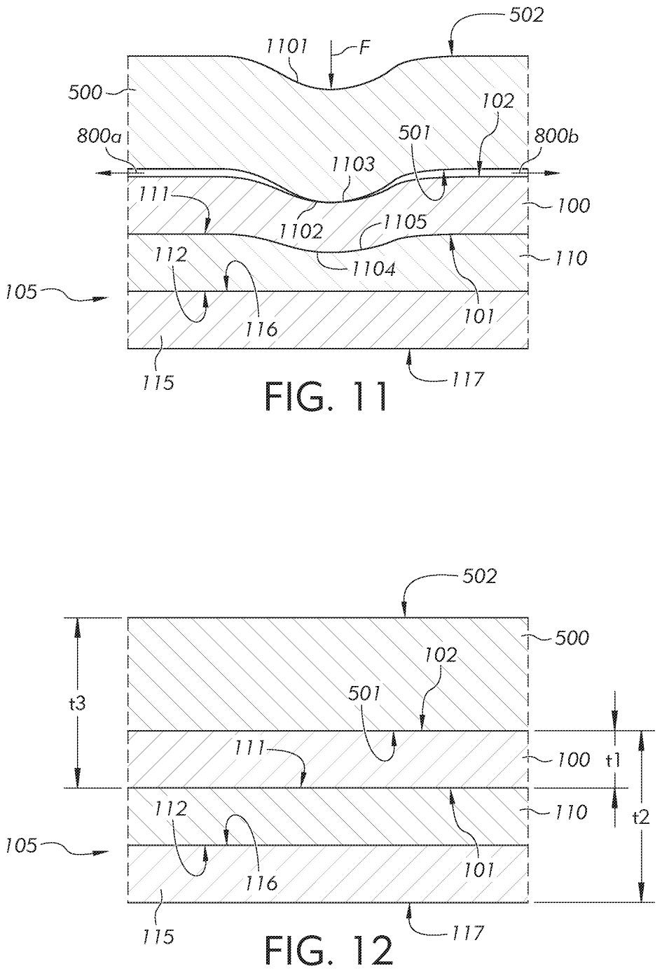

Turning to FIG. 11, which illustrates a partial cross-sectional view along line 11-11 of FIG. 10, in some embodiments, applying the force “F” to the location (e.g., the point 1001, the axis 1002) of the second major surface 502 of the second carrier 500 may deform a portion 1101 of the second major surface 502 of the second carrier 500 toward the substrate 100. Based at least on the deformation of the portion 1101 of the second major surface 502 of the second carrier 500, a portion 1102 of the first major surface 501 of the second carrier 500 may also deform toward the substrate 100. The deformed portion 1102 of the first major surface 501 of the second carrier 500 may contact the second major surface 102 of the substrate 100.

Based at least on the contact between the portion 1102 of the first major surface 501 of the second carrier 500 and the second major surface 102 of the substrate 100, the portion 1102 of the first major surface 501 of the second carrier 500 may bond to the second major surface 102 of the substrate 100.

Additionally, based at least on the contact between the portion 1102 of the first major surface 501 of the second carrier 500 and the second major surface 102 of the substrate 100, a portion 1103 of the second major surface 102 of the substrate 100 may deform toward the first carrier 105. Based at least on the deformation of the portion 1103 of the second major surface 102 of the substrate 100, a portion 1104 of the first major surface 101 of the substrate 100 may also deform toward the first carrier 105. Based at least on the deformation of the portion 1104 of the first major surface 101 of the substrate 100, a portion 1105 of the first major surface 111 of the first carrier 105 may also deform. For example, in embodiments where the first carrier 105 includes the first layer 110 and the second layer 115, based at least on the deformation of the portion 1104 of the first major surface 101 of the substrate 100, a portion 1105 of the first major surface 111 of the first layer 110 may deform toward the second layer 115. That is, in some embodiments, based at least on the deformation of the portion 1104 of the first major surface 101 of the substrate 100, a portion 1105 of the first major surface 111 of the first layer 110 of the first carrier 105 may deform toward at least one of the second major surface 112 of the first layer of the first carrier 105, the first major surface 116 of the second layer 115 of the first carrier 105, and the second major surface 117 of the second layer 115 of the first carrier 105. In some embodiments, the portion 1105 of the first major surface 111 of the first layer 110 may deform without deforming the second layer 115. For example, as mentioned previously, the material of the second layer 115 may have a greater stiffness than the material of the first layer 110 to allow deformation of the first layer 110 without a corresponding deformation of the second layer 115.

After applying the force “F” to the location (e.g., the point 1001, the axis 1002) of the second major surface 502 of the second carrier 500, the method may then include ceasing to apply the force “F” to allow a bond front (bonding the first major surface 501 of the second carrier 500 to the second major surface 102 of the substrate 100) to propagate away from the location. For example, as shown in FIG. 10, with respect to the location defining the point 1001, the bond front may propagate away from the point 1001, as schematically illustrated by arrows 1001a, 1001b, 1001c, and 1001d, after ceasing to apply the force “F”. Similarly, with respect to the location defining the axis 1002, the bond front may propagate away from the axis 1002, as schematically illustrated by arrows 1002a, 1002b, 1002c, and 1002d, after ceasing to apply the force “F”.

In some embodiments, after ceasing to apply the force “F”, the force deforming the portion 1105 of the first major surface 111 of the first carrier 105 may balance. Based at least on the balancing of the force, the deformed portion 1105 of the first major surface 111 of the first carrier 105 may move in a direction opposite the direction in which it deformed to provide the first major surface 111 in an equilibrium state, where all forces acting on the first major surface 111 are at least one of balanced and zero.

Similarly, after ceasing to apply the force “F”, the force deforming the portion 1104 of the first major surface 101 of the substrate 100 and the force deforming the portion 1103 of the second major surface 102 of the substrate 100 may balance. Based at least on the balancing of the force, the deformed portion 1104 of the first major surface 101 of the substrate 100 and the deformed portion 1103 of the second major surface 102 of the substrate 100 may move in a direction opposite the direction in which they deformed to provide the first major surface 101 and the second major surface 102 of the substrate 100 in an equilibrium state, where all forces acting on the first major surface 101 and the second major surface 102 are at least one of balanced and zero.

Likewise, after ceasing to apply the force “F”, the force deforming the portion 1102 of the first major surface 501 of the second carrier 500 and the force deforming the portion 1101 of the second major surface 502 of the second carrier 500 may balance. Based at least on the balancing of the force, the deformed portion 1102 of the first major surface 501 of the second carrier 500 and the deformed portion 1101 of the second major surface 502 of the second carrier 500 may move in a direction opposite the direction in which they deformed to provide the first major surface 501 and the second major surface 502 in an equilibrium state, where all forces acting on the first major surface 501 and the second major surface 502 are at least one of balanced and zero.

Without intending to be bound by theory, after ceasing to apply the force “F”, the bond front may naturally propagate (e.g., without external influence) from the location based at least on equilibration of one or more of the deformed portions of the substrate 100, the first carrier 105, and the second carrier 500. Additionally, as shown in FIG. 11 by arrows 800a and 800b, gas within the gap 800 (shown in FIG. 8) may be expelled from between the first major surface 501 of the second carrier 500 and the second major surface 102 of the substrate 100 as the bond front naturally propagates away from the location. Accordingly, as the deformed portions of the substrate 100, the first carrier 105, and the second carrier 500 equilibrate, gas may be expelled from the gap 800 between the first major surface 501 of the second carrier 500 and the second major surface 102 of the substrate 100, the bond front naturally propagates away from the location, and the first major surface 501 of the second carrier 500 bonds to the second major surface 102 of the substrate 100.

Bonding between the first major surface 501 of the second carrier 500 and the second major surface 102 of the substrate 100 may include direct contact between the first major surface 501 and the second major surface 102 where, for example, Van der Waals forces bond the first major surface 501 to the second major surface 102. Alternatively or in addition, in some embodiments, a binding agent, for example a polymer binding agent, a silicone binding agent, or other binding agents may be positioned between the first major surface 501 of the second carrier 500 and the second major surface 102 of the substrate 100 to bond between the first major surface 501 and the second major surface 102.

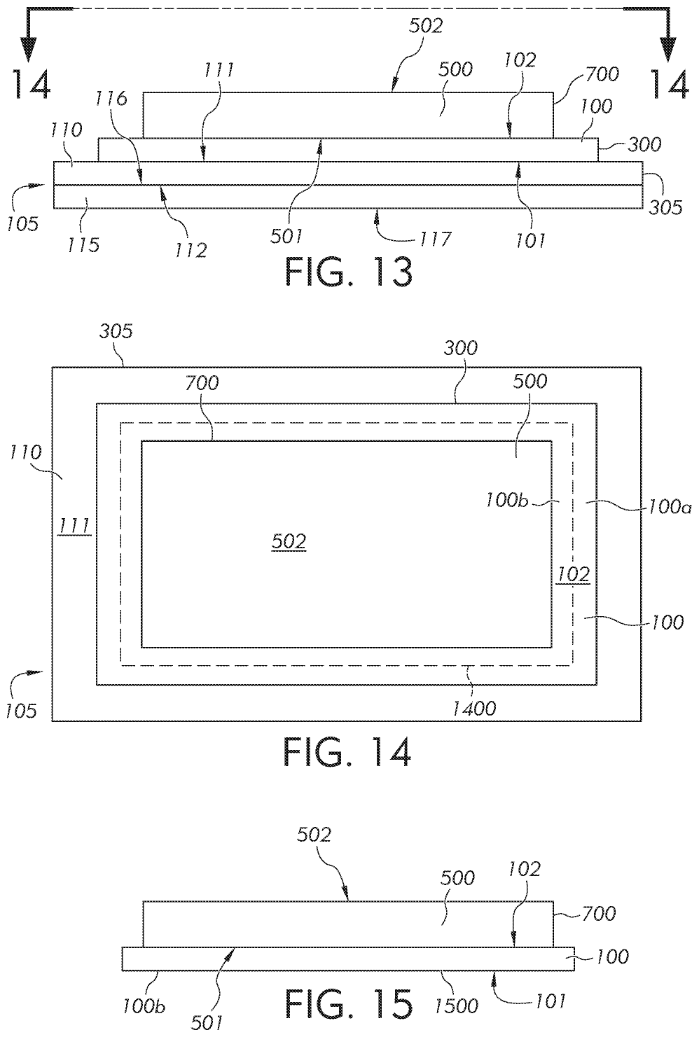

As shown in FIG. 12 and FIG. 13, once the bond front has finished naturally propagating, the first major surface 501 of the second carrier 500 and the second major surface 102 of the substrate 100 may be bonded together. In some embodiments, natural propagation of the bond front may provide a bonded interface between the first major surface 501 and the second major surface 102 that may be substantially free from bubbles (e.g., trapped pockets of gas) between the first major surface 501 and the second major surface 102. In some embodiments, a bond force between the first major surface 501 and the second major surface 102 at the region of a bubble may be at least one of reduced or non-existent as compared to a bond force between the first major surface 501 and the second major surface 102 at a region substantially free from bubbles. Accordingly, in some embodiments, natural propagation of the bond front may provide a bonded interface between the first major surface 501 of the second carrier 500 and the second major surface 102 of the substrate 100 that may be stronger than a bonded interface achieved by other bonding methods.

Additionally, in some embodiments, natural propagation of the bond front may provide the substrate 100 with a planar profile after the substrate 100 is bonded to the second carrier 500. For example, after the substrate 100 is bonded to the second carrier 500, the substrate 100 may be substantially warp free, and the first major surface 101 of the substrate 100 may be planar, the second major surface 102 of the substrate 100 may be planar, and the first major surface 101 may be parallel to the second major surface 102. Because warping of the substrate 100 may introduce problems during processing, for example, when attaching functional components (e.g., a color filter, touch sensor, or thin-film transistor (TFT) components) to the substrate 100, a substantially warp free substrate 100 may provide several advantages when processing the substrate 100. Moreover, because warping of the substrate 100 may also be undesirable when the substrate 100 is employed in the production of electronic devices for display applications, a substantially warp free substrate 100 may provide several advantages when the substrate 100 is employed in electronic devices for display applications.

In some embodiments, existing production equipment may be configured to process a structure having a predetermined thickness. Turning back to FIG. 12, in some embodiments, the thickness “t1” of the substrate 100 in combination with a thickness of the second carrier 500 may, therefore, be selected to provide a thickness “t3” of the bonded structure, between the first major surface 101 of the substrate 100 and the second major surface 502 of the second carrier 500, equal to the predetermined thickness for which existing production equipment may be configured to process. Thus, in some embodiments, processing may be performed by employing existing production equipment in which a bonded structure including the substrate 100 bonded to the second carrier 500 provides, for example, characteristics and size that allow the bonded structure to be handled and transported in the production equipment without significant modification to the production equipment. In some embodiments, the thickness “t3” may be from about 300 microns to about 750 microns from about 300 microns to about 1 millimeter, from about 1 millimeter to about 2 millimeters; however, in some embodiments, the thickness “t3” of the bonded structure may be greater than or less than the explicit dimensions provided in the disclosure without departing from the scope of the disclosure.

The method may further include debonding the first major surface 111 of the first carrier 105 from the first major surface 101 of the substrate 100. Debonding may be performed by one or more of peeling, prying, and lifting at least one of the substrate 100 and the first carrier 105 to overcome the first bond force bonding the first major surface 101 of the substrate 100 to the first major surface 111 of the first carrier 105. Relative displacement of the substrate 100 and the first carrier 105 based at least on the one or more peeling, prying, and lifting of at least one of the substrate 100 and the first carrier 105 may debond and separate (e.g., completely separate) the substrate 100 from the first carrier 105. In some embodiments, a first bond force bonding the first major surface 101 of the substrate 100 to the first major surface 111 of the first carrier 105 may be less than a second bond force bonding the second major surface 102 of the substrate 100 to the first major surface 501 of the second carrier 500. Accordingly, if the second bond force, bonding the second major surface 102 of the substrate 100 to the first major surface 501 of the second carrier 500, is greater than the first bond force, bonding the first major surface 101 of the substrate 100 to the first major surface 111 of the first carrier 105, the one or more of the peeling, prying, and lifting of at least one of the substrate 100 and the first carrier 105 will overcome the first bond force before overcoming the second bond force. Thus, in some embodiments, the substrate 100 may be debonded from the first carrier 105 without disturbing the second bond force and without debonding the substrate 100 from the second carrier 500.

Turning to FIG. 14, in some embodiments, prior to debonding the first carrier 105 from the substrate 100, the method may include separating an outer circumferential portion 100a of the substrate 100 from a central portion 100b of the substrate 100. In some embodiments, separating the outer circumferential portion 100a from the central portion 100b may include scoring the substrate 100 (e.g., the second major surface 102) with a tool (e.g., score wheel, laser, etc.) along a separation path 1400, and then separating the outer circumferential portion 100a from the central portion 100b along the separation path 1400. In some embodiments, separating the outer circumferential portion 100a from the central portion 100b prior to debonding the first major surface 111 of the first carrier 105 from the first major surface 101 of the substrate 100 may provide several advantages. For example, in some embodiments, the first carrier 105 may support the substrate 100 while separating the outer circumferential portion 100a from the central portion 100b along the separation path 1400. For example, the first carrier 105 may hold the outer circumferential portion 100a and the central portion 100b and at least one of prevent and reduce movement (e.g., dampen vibration) of at least one of the outer circumferential portion 100a and the central portion 100b while separating the outer circumferential portion 100a from the central portion 100b along the separation path 1400.

Without intending to be bound by theory, in some embodiments, the outer circumferential portion 100a of the substrate 100 may be separated from the central portion 100b of the substrate 100 with a higher probability of success by at least one of preventing and reducing movement of the at least one of the outer circumferential portion 100a and the central portion 100b, as compared to, for example, separating the outer circumferential portion 100a from the central portion 100b without supporting at least one of the outer circumferential portion 100a and the central portion 100b. For example, supporting at least one of the outer circumferential portion 100a and the central portion 100b while separating the outer circumferential portion 100a from the central portion 100b may at least one of prevent and reduce cracks, chips, and breaks in the substrate 100 along the separation path 1400 caused by the separation that may otherwise be present if at least one of the outer circumferential portion 100a and the central portion 100b is not supported by the first carrier 105. Alternatively or in addition, in some embodiments, separating the outer circumferential portion 100a from the central portion 100b when the substrate 100 is bonded to the first carrier 105 may advantageously allow the first carrier 105 to act as a handle for the circumferential portion 100a. That is, the outer circumferential portion 100a may be moved relative to (e.g., away from) the central portion 100b by manipulating the first carrier 105. Thus, in some embodiments, the first carrier 105 may contain the material of the circumferential portion 100a from breaking apart and forming debris that may land on the central portion 100b.

FIG. 15, shows the second major surface 102 of the substrate 100 bonded to the first major surface 501 of the second carrier 500 after separating the outer circumferential portion 100a of the substrate 100 from the central portion 100b of the substrate and after debonding the first major surface 111 of the first carrier from the first major surface 101 of the substrate 100. In some embodiments, after debonding the first major surface 111 of the first carrier 105 from the first major surface 101 of the substrate 100, the first major surface 101 of the substrate 100 may include an exposed area 1500. The method of processing the substrate 100 may then include processing the exposed area 1500 of the first major surface 101 of the substrate 100. In some embodiments, processing the exposed area 1500 may include heating the exposed area 1500 at a temperature greater than about 300 degrees Celsius. In some embodiments, processing the exposed area 1500 may include attaching functional components (e.g., a color filter, touch sensor, or thin-film transistor (TFT) components) to the first major surface 101 of the substrate 100. In some embodiments, processing the exposed area 1500 may include washing the exposed area 1500 with a liquid. In some embodiments, washing the exposed area 1500 with a liquid may remove debris (e.g., dirt, dust, particles, etc.) that may be deposited on the exposed area 1500.

In some embodiments, the first major surface 111 of the first carrier 105 may be debonded from the first major surface 101 of the substrate 100 without separating the outer circumferential portion 100a of the substrate 100 from the central portion 100b of the substrate 100. Additionally, based at least on the methods of bonding the substrate 100 to the first carrier 105 and the second carrier 500, after debonding the first carrier 105 from the substrate 100, the substrate 100, including the exposed area 1500 of the first major surface 101 of the substrate 100, may be substantially warp free. For example, after debonding the first carrier 105 from the substrate 100, the first major surface 101 of the substrate 100 may be planar, the second major surface 102 of the substrate 100 may be planar, and the first major surface 101 may be parallel to the second major surface 102.

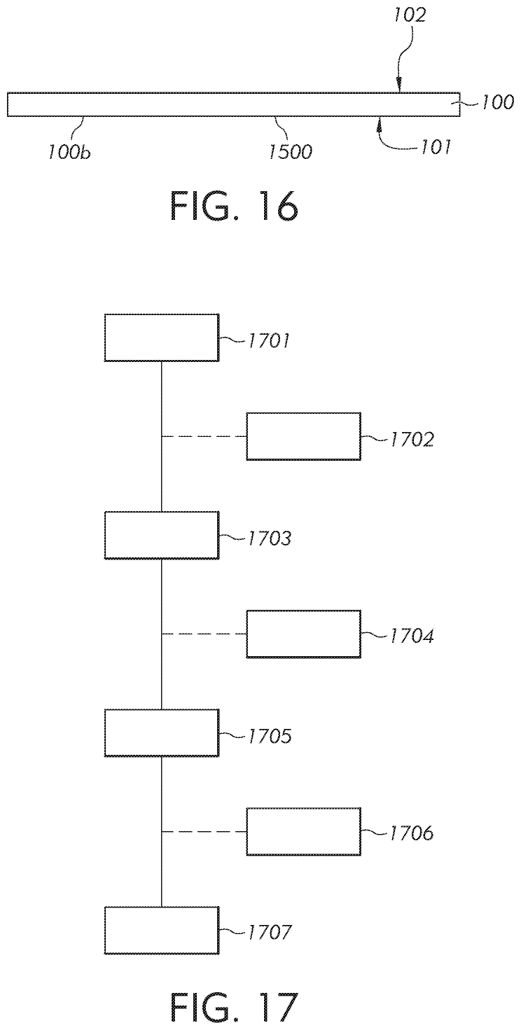

As shown in FIG. 16, after processing the exposed area 1500 of the first major surface 101 of the substrate 100, in some embodiments, the method may include debonding the first major surface 501 of the second carrier 500 from the second major surface 102 of the substrate 100. Debonding may be performed by one or more of peeling, prying, and lifting at least one of the substrate 100 and the second carrier 500 to overcome the second bond force bonding the second major surface 102 of the substrate 100 to the first major surface 501 of the second carrier 500. Relative displacement of the substrate 100 and the second carrier 500 based at least on the one or more peeling, prying, and lifting of at least one of the substrate 100 and the second carrier 500 may debond and separate (e.g., completely separate) the substrate 100 from the second carrier 500.

Based at least on the methods of bonding the substrate 100 to the first carrier 105 and the second carrier 500, after debonding the second carrier 500 from the substrate 100, the substrate 100, including the exposed area 1500 of the first major surface 101 of the substrate 100, may be substantially warp free. For example, after debonding the first carrier 105 from the substrate 100, the first major surface 101 of the substrate 100 may be planar, the second major surface 102 of the substrate 100 may be planar, and the first major surface 101 may be parallel to the second major surface 102. Accordingly, after separating the substrate 100 and the second carrier 500, the substrate 100, including any functional components (e.g., a color filter, touch sensor, or thin-film transistor (TFT) components) attached to at least one of the first major surface 101 of the substrate 100 and the second major surface 102 of the substrate 100 may be provided and employed in electronic devices for display applications or any other application in which the substrate 100 may find utility.

FIG. 17 shows a flowchart of exemplary method steps of processing the substrate 100 in accordance with embodiments of the disclosure. For example, step 1701 may correspond to one or more features of bonding the first major surface 101 of the substrate 100 to the first major surface 111 of the first carrier 105. Step 1703 may correspond to one or more features of bonding the second major surface 102 of the substrate 100 to the first major surface 501 of the second carrier 500 after step 1701 of bonding the first major surface 101 of the substrate 100 to the first major surface 111 of the first carrier 105. Step 1702 may correspond to one or more features of the optional step of processing the exposed area 200 of the second major surface 102 of the substrate 100 after step 1701 of bonding the first major surface 101 of the substrate 100 to the first major surface 111 of the first carrier 105 and prior to step 1703 of bonding the second major surface 102 of the substrate 100 to the first major surface 501 of the second carrier 500. Step 1705 may correspond to one or more features of debonding the substrate 100 from the first carrier 105, for example, after step 1703 of bonding the second major surface 102 of the substrate 100 to the first major surface 501 of the second carrier 500. Step 1704 may correspond to one or more features of the optional step of separating the outer circumferential portion 100a of the substrate 100 from the central portion 100b of the substrate 100 after step 1703 of bonding the second major surface 102 of the substrate 100 to the first major surface 501 of the second carrier 500 and prior to step 1705 of debonding the substrate 100 from the first carrier 105. Step 1707 may correspond to one or more features of debonding the substrate 100 from the second carrier 500, for example, after step 1705 of debonding the substrate 100 from the first carrier 105. Step 1706 may correspond to one or more features of the optional step of processing the exposed area 1500 of the first major surface 101 of the substrate 100 after step 1705 of debonding the substrate 100 from the first carrier 105 and prior to step 1707 of debonding the substrate 100 from the second carrier 500.

One or more features of any one or more steps 1701, 1702, 1703, 1704, 1705, and 1706 may be employed either alone or in combination to process the substrate 100 in accordance with embodiments of the disclosure to provide a substrate 100 that may be employed in electronic devices for display applications or any other application in which the substrate 100 may find utility.

Directional terms as used herein—for example up, down, right, left, front, back, top, bottom—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In some embodiments, “substantially similar” may denote values within about 10% of each other, such as within about 5% of each other, or within about 2% of each other.

The above embodiments, and the features of those embodiments, are exemplary and may be provided alone or in any combination with any one or more features of other embodiments provided herein without departing from the scope of the disclosure.

It will be apparent to those skilled in the art that various modifications and variations may be made to the present disclosure without departing from the spirit and scope of the disclosure. Thus, it is intended that the present disclosure cover the modifications and variations of this disclosure provided they come within the scope of the appended claims and their equivalents.

1. A method of processing a substrate comprising:
bonding a first major surface of the substrate to a first major surface of a first carrier;
positioning a second carrier with a first major surface of the second carrier facing a second major surface of the substrate; and then
applying a force to a location of a second major surface of the second carrier thereby deforming a portion of the first major surface of the second carrier and a portion of the second major surface of the second carrier toward the substrate, the deformed portion of the first major surface of the second carrier contacts the second major surface of the substrate thereby deforming a portion of the first major surface of the substrate and a portion of the second major surface of the substrate toward the first carrier, the deformed portion of the first major surface of the substrate deforms a portion of the first major surface of the first carrier toward a second major surface of the first carrier.

2. The method of claim 1, further comprising ceasing to apply the force to allow a bond front to propagate away from the location, thereby bonding the first major surface of the second carrier to the second major surface of the substrate.

3. The method of claim 1, wherein the location defines a point on the second major surface of the second carrier.

4. The method claim 1, wherein the location defines an axis extending across the second major surface of the second carrier.

5. The method of claim 1, wherein a thickness of the substrate defined between the first major surface of the substrate and the second major surface of the substrate is from about 50 microns to about 300 microns.

6. The method of any one of claim 1, wherein the material of the substrate is selected from the group consisting of glass, glass-ceramic, ceramic, and silicon.

7. The method of any one of claim 1, wherein the first carrier comprises polyurethane.

8. The method of claim 1, wherein the first carrier comprises a first layer comprising a first material and a second layer comprising a second material, the first material defines the first major surface of the first carrier, and a stiffness of the second material is greater than a stiffness of the first material.

9. The method of claim 8, wherein the first material is polyurethane.

10. The method of claim 9, wherein the second material is selected from the group consisting of glass, glass-ceramic, ceramic, silicon, plastic, and metal.

11. A method of processing a substrate comprising:
bonding a first major surface of the substrate to a major surface of a first carrier, the first carrier comprises a first layer comprising a first material and a second layer comprising a second material, the first material defines the major surface of the first carrier, and a stiffness of the second material is greater than a stiffness of the first material; then
bonding a second major surface of the substrate to a major surface of a second carrier; and then
debonding the major surface of the first carrier from the first major surface of the substrate.

12. The method of claim 11, wherein a thickness of the substrate defined between the first major surface of the substrate and the second major surface of the substrate is from about 50 microns to about 300 microns.

13. The method of claim 11, wherein the material of the substrate is selected from the group consisting of glass, glass-ceramic, ceramic, and silicon.

14. The method of claim 11, wherein the first material is polyurethane.

15. The method of claim 11, wherein the second material is selected from the group consisting of glass, glass-ceramic, ceramic, silicon, plastic, and metal.

16. The method of claim 11, wherein an outer peripheral edge of the first carrier laterally circumscribes an outer peripheral edge of the substrate.

17. The method of claim 11, wherein an outer peripheral edge of the substrate laterally circumscribes an outer peripheral edge of the second carrier.

18. The method of claim 11, wherein a first bond force bonding the first major surface of the substrate to the major surface of the first carrier is less than a second bond force bonding the second major surface of the substrate to the major surface of the second carrier.

19. The method of claim 11, further comprising separating an outer circumferential portion of the substrate from a central portion of the substrate prior to debonding the major surface of the first carrier from the first major surface of the substrate.

20. The method of claim 11, further comprising processing an exposed area of the second major surface of the substrate after bonding the first major surface of the substrate to the major surface of the first carrier and prior to bonding the second major surface of the substrate to the major surface of the second carrier.

21. The method of claim 20, wherein the processing the exposed area of the second major surface of the substrate comprises washing the exposed area of the second major surface of the substrate with a liquid.

22. The method of claim 11, further comprising processing an exposed area of the first major surface of the substrate after debonding the major surface of the first carrier from the first major surface of the substrate.

23. The method of claim 22, wherein the processing the exposed area of the first major surface of the substrate comprises heating the exposed area of the first major surface of the substrate at a temperature greater than or equal to about 300° C.

24. The method of claim 11, further comprising debonding the major surface of the second carrier from the second major surface of the substrate after debonding the major surface of the first carrier from the first major surface of the substrate.

25. The method of claim 11, wherein the bonding the second major surface of the substrate to the major surface of the second carrier comprises positioning the second carrier with the major surface of the second carrier facing the second major surface of the substrate; and then
applying a force to a location of an opposing major surface of the second carrier thereby deforming a portion of the major surface and a portion of the opposing major surface of the second carrier toward the substrate, the deformed portion of the major surface of the second carrier contacts the second major surface of the substrate thereby deforming a portion of the first major surface and a portion of the second major surface of the substrate toward the first carrier, the deformed portion of the first major surface of the substrate deforms a portion of the major surface of the first carrier toward an opposing major surface of the first carrier.

26. The method of claim 25, further comprising ceasing to apply the force to allow a bond front to propagate away from the location, thereby bonding the major surface of the second carrier to the second major surface of the substrate.

27. The method of claim 25, wherein the location defines a point on the opposing major surface of the second carrier.

28. The method claim 25, wherein the location defines an axis extending across the opposing major surface of the second carrier.
